(19) United States
(12) Patent Application Publication
(10) Pub. No.: US 2025/0248198 A1
(43) Pub. Date: Jul. 31, 2025

(54) DISPLAY PANEL AND DISPLAY DEVICE

(71) Applicant: KunShan Go-Visionox Opto-Electronics Co., Ltd., Kunshan (CN)

(72) Inventors: Junlin HU, Kunshan (CN); Wentao YING, Kunshan (CN); Rubo XING, Kunshan (CN); Yiming JIA, Kunshan (CN); Xiaokang ZHOU, Kunshan (CN); Yanhua CHENG, Kunshan (CN); Xingxing YANG, Kunshan (CN)

(73) Assignee: KunShan Go-Visionox Opto-Electronics Co., Ltd., Kunshan (CN)

(21) Appl. No.: 19/185,208

(22) Filed: Apr. 21, 2025

Related U.S. Application Data
(63) Continuation of application No. PCT/CN2023/078718, filed on Feb. 28, 2023.

(30) Foreign Application Priority Data
Oct. 28, 2022 (CN) 202211339004.3

(51) Int. Cl. H10H 29/85; G06F 3/044; H10H 29/854; H10H 29/855

(52) U.S. Cl. CPC H10H 29/8517; G06F 3/0446; H10H 29/854; H10H 29/8552

(57) ABSTRACT

The disclosure provides a display panel and a display device. The display panel includes a display substrate and a lens structure. The display substrate includes a plurality of light-emitting devices and a receiving layer located on light-emitting sides of the light-emitting devices. The lens structure is located on the receiving layer and includes a plurality of lens units, and the lens units are arranged in correspondence with the light-emitting devices. Each of the lens units includes a color blocking layer configured to absorb light in ambient light that is different in color from light emitted from a corresponding light-emitting device. The lens unit has a refractive index greater than a refractive index of the receiving layer.

### CROSS-REFERENCE TO RELATED APPLICATIONS

The present application a continuation of International Application No. PCT/CN2023/078718 filed on Feb. 28, 2023, which claims priority to Chinese Patent Application No. 202211339004.3, filed on Oct. 28, 2022. All of the aforementioned patent applications are hereby incorporated by reference in their entireties.

### FIELD

The disclosure relates to the field of display, and in particular to a display panel and a display device including the display panel.

### BACKGROUND

With the progress of the society and the development of science and technology, electronic display products are widely applied in daily work and life, and have promising development prospects.

However, current electronic display products have an inefficient low light output due to limitations on their own structural designs. In order to ensure the luminous brightness of the electronic display products, it is required to improve the luminous efficiency thereof, but this also increases the power consumption and reduces the service life of the electronic display products.

### SUMMARY

One embodiment of the disclosure provides a display panel. The display panel includes a display substrate and a lens structure. The display substrate includes a plurality of light-emitting devices and a receiving layer located on light-emitting sides of the light-emitting devices. The lens structure is located on the receiving layer and includes a plurality of lens units, and the lens units are arranged in correspondence with the light-emitting devices. Each of the lens units includes a color blocking layer configured to absorb light in ambient light that is different in color from light emitted from a corresponding light-emitting device. The lens unit has a refractive index greater than a refractive index of the receiving layer.

In the above solution, the lens unit actually integrates functions of a lens and a color filter, which is conducive to the lightweight and thin design of the display panel and an increase in the arrangement density of the light-emitting devices, so that the display panel is designed to have a higher resolution.

One embodiment of the disclosure provides a display device, including a display panel according to the embodiments described above.

### BRIEF DESCRIPTION OF THE DRAWINGS

FIG. 1 is a schematic diagram of a planar structure of a display panel according to an embodiment of the disclosure.

FIG. 2 is a sectional view of a design structure of the display panel shown in FIG. 1 along line M-N.

FIG. 3 is a partial structural schematic diagram of the cross section shown in FIG. 2.

FIG. 4 is a sectional view of an alternative design structure of the display panel shown in FIG. 1 along line M-N.

FIG. 5 is a sectional view of an alternative design structure of the display panel shown in FIG. 1 along line M-N.

FIG. 6 is a sectional view of an alternative design structure of the display panel shown in FIG. 1 along line M-N.

FIG. 7A is a sectional view of an alternative design structure of the display panel shown in FIG. 1 along line M-N.

FIG. 7B is a sectional view of an alternative design structure of the display panel shown in FIG. 1 along line M-N.

FIG. 8 is a sectional view of an alternative design structure of the display panel shown in FIG. 1 along line M-N.

FIG. 9A is a sectional view of an alternative design structure of the display panel shown in FIG. 1 along line M-N.

FIG. 9B is a sectional view of an alternative design structure of the display panel shown in FIG. 1 along line M-N.

FIG. 10 is a sectional view of an alternative design structure of the display panel shown in FIG. 1 along line M-N.

FIG. 11 is a sectional view of an alternative design structure of the display panel shown in FIG. 1 along line M-N.

FIG. 12 is a sectional view of an alternative design structure of the display panel shown in FIG. 1 along line M-N.

FIG. 13 is an enlarged view of an area S of the display panel shown in FIG. 12.

FIG. 14 is a sectional view of an alternative design structure of the display panel shown in FIG. 1 along line M-N.

FIG. 15 is a sectional view of an alternative design structure of the display panel shown in FIG. 1 along line M-N.

FIG. 16 is a sectional view of an alternative design structure of the display panel shown in FIG. 1 along line M-N.

FIG. 17 is a sectional view of an alternative design structure of the display panel shown in FIG. 1 along line M-N.

FIG. 18 is a sectional view of an alternative design structure of the display panel shown in FIG. 1 along line M-N.

FIG. 19 is a sectional view of an alternative design structure of the display panel shown in FIG. 1 along line M-N.

FIG. 20 is a sectional view of an alternative design structure of the display panel shown in FIG. 1 along line M-N.

FIG. 21 is a sectional view of an alternative design structure of the display panel shown in FIG. 1 along line M-N, where the display panel has a touch function.

FIG. 22 is a sectional view of an alternative design structure of the display panel shown in FIG. 1 along line M-N, where the display panel has a touch function.

FIG. 23 is a schematic diagram of simulation results of an optical effect of a display panel according to an embodiment of the disclosure.

### DETAILED DESCRIPTION OF EMBODIMENTS

The embodiments of the specification will be clearly and completely described below in conjunction with the accompanying drawings in the embodiments of the specification. Apparently, the embodiments described are merely some rather than all of the embodiments of the specification.

In a display panel, it is required to collimate emergent light by arranging micro-lenses on light-emitting sides of sub-pixels (light-emitting devices therein), in order to increase the luminous brightness in a front viewing angle direction, accordingly reduce the requirements for the luminous efficiency of the display panel, also reduce the power consumption of the display panel and prolong the service life of the display panel. In this way, the smaller a distance between the micro-lens and a light source (light-emitting device) of the sub-pixel is, the more light emitted from the light source can be regulated and controlled by the micro-lens, and the smaller a plane size required by the micro-lens is.

In addition, color filters can be arranged on a display side of the display panel to eliminate the visibility of ambient light. Compared with a method for eliminating ambient light by simply arranging polarizers, the method of arranging the color filters can allow the display panel to have a higher light transmittance in order to further improve the light output efficiency of the display panel. In this way, the smaller a distance between the color filter and the light source (light-emitting device) of the sub-pixel is, the smaller the plane size required by the color filter is while it is ensured that more light emitted from the light source can pass through the color filter.

In addition, areas where the color filters corresponding to different sub-pixels are located are typically defined by a black matrix, and accordingly the black matrix actually defines light-emitting areas of the sub-pixels. In this way, a film layer where the black matrix is located and a film layer (color film) where the color filters are located need to be arranged together, alternatively spaced by a small distance, such that the black matrix can delimit the ranges of respective color filters (or the ranges of the light-emitting areas of the sub-pixels).

As two separate components, the color filter and the micro-lens are arranged at an interval in different layers, such that one (assumed to be the color filter) of the color filter and the micro-lens is at a larger distance from the light source, it is thus required to design the color filter or the micro-lens to have a larger size, and the sub-pixels also need to have a relatively larger spacing while it is ensured that the display panel can display an image at a large viewing angle, which is equivalent to decreasing the design density of the sub-pixels and thus reducing the resolution of the display panel.

It should be understood that arranging a black matrix in the vicinity of the film layer where the color filters are located in the display panel is an alternative design solution, whether or not to design the black matrix can be determined according to actual requirements, and no black matrix may be arranged in the vicinity of the film layer where the color filters are located by defining the light-emitting areas and the ranges of light-emitting angles of the sub-pixels otherwise (for example, a pixel definition layer for defining the positions of the light-emitting devices is designed to be black, etc.).

In view of this, at least one embodiment of the disclosure provides a display panel. The display panel includes a display substrate and a lens structure. The display substrate includes a plurality of light-emitting devices and a receiving layer located on light-emitting sides of the light-emitting devices. The lens structure is located on the receiving layer and includes a plurality of lens units, and the lens units are arranged in correspondence with the light-emitting devices. Each of the lens units includes a color blocking layer. The color blocking layer may include a color blocking material corresponding to the light-emitting device to absorb light in ambient light that is different in color from the light emitted from a corresponding light-emitting device. The lens unit has a refractive index greater than a refractive index of the receiving layer, such that ambient light is at a junction of the lens unit and the receiving layer when entering the display panel, which is equivalent to entering an optically thinner medium from an optically denser medium, thus reflecting part of the ambient light. In addition, the emergent light of the display panel enters the optically denser medium from the optically thinner medium at the junction and is collimated (trends to be at a front viewing angle) for emergence, and thus the light output efficiency is improved. In this way, the color blocking layer including the color blocking material actually serves as the color filters, that is, the lens units actually integrate the functions of lenses and the color filters without a separately arranged color film (including the color filters arranged in an array), which is conducive to the lightweight and thin design of the display panel; moreover, with this design, the direction regulation and control (e.g., including collimation) are performed on the emergent light from the light-emitting devices and distances between the positions of the color filters and the light-emitting devices are all small, that is, the spacings between the light-emitting devices and the color blocking layer (color filters) and the lens units (micro-lenses) are small; if it is maintained that the display panel can display at the large viewing angle, the lens units (the color filters and the micro-lenses) can have a smaller coverage area (planar area), and accordingly there is a smaller spacing between different sub-pixels (corresponding to the light-emitting devices), which is conducive to increasing the arrangement density of the sub-pixels and thus designing the display panel to have a higher resolution.

A structure of a display panel according to at least one embodiment of the disclosure will be described below with reference to the figures. In these embodiments, a spatial rectangular coordinate system is established on the basis of a display substrate (e.g., a display surface thereof) to describe the position of each structure in the display panel. In this spatial rectangular coordinate system, an X-axis and a Y-axis are parallel to the display substrate, and a Z-axis is perpendicular to the display substrate.

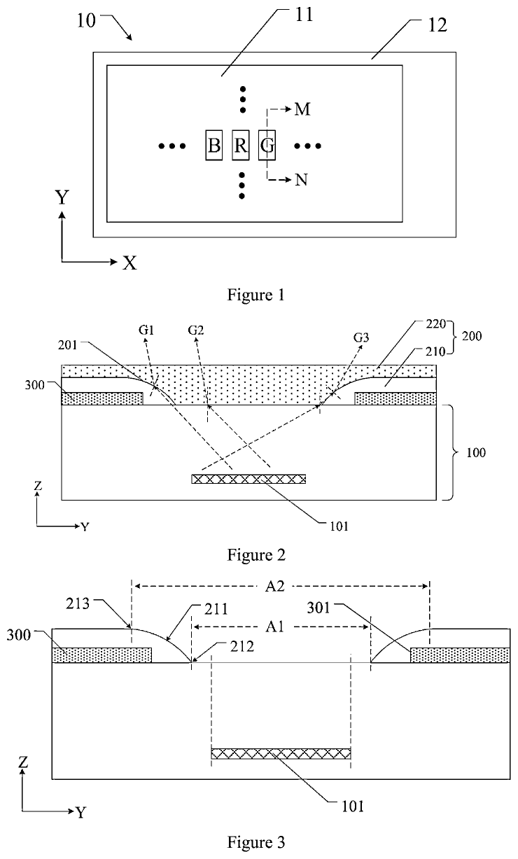

FIG. 1 is a schematic diagram of a planar structure of a display panel according to an embodiment of the disclosure, FIG. 2 is a sectional view of a design structure of the display panel shown in FIG. 1 along line M-N, and FIG. 3 is a partial structural schematic diagram of the cross section shown in FIG. 2.

In at least one embodiment of the disclosure, as shown in FIGS. 1-3, a planar area of a display panel 10 may be divided into an active area 11 and a border area 12 surrounding the active area 11, where the active area 11 is configured to arrange sub-pixels to display an image, and the border area 12 is configured for wiring and circuit switching (e.g., bonding a chip or a flexible circuit board, etc.). A solid structure of the display panel 10 includes a display substrate 100 and a lens structure. The display substrate 100 includes a plurality of light-emitting devices 101, and the light-emitting devices 101 are located in the active area 11 to form main light-emitting structures of the sub-pixels (e.g., three sub-pixels R, G, B in FIG. 1). The lens structure is located in the active area 11 and on a light-emitting side of the display substrate 100. The lens structure includes a plurality of lens units 200, and the lens units 200 are arranged in one-to-one correspondence with the light-emitting devices 101 to adjust light exit directions of corresponding light-emitting devices 101. Each of the lens units 200 includes a color blocking layer, the color blocking layer includes a color blocking material, and the color of the color blocking material of the lens unit 200 is the same as a light-emitting color of a corresponding sub-pixel. Specifically, as shown in FIGS. 1 and 2, the color blocking material of the lens unit 200 corresponding to the sub-pixel G is green.

It should be understood that in the embodiments of the disclosure, the color blocking layer may be made of only the color blocking material or may be made by doping a base material with the color blocking material. In the following embodiment, in order to briefly describe the embodiments, it will be directly expressed that these structures are made of the color blocking material if the color blocking layer or relevant structures described (e.g., a first sub-film layer described below) includes the color blocking material.

In at least one embodiment of the disclosure, the lens unit includes a first film layer and a second film layer. The first film layer includes a plurality of first recesses corresponding to the light-emitting devices. The first recesses are filled with at least part of the second film layer. The first film layer has a refractive index less than a refractive index of the at least part of the second film layer that is filled in the first recesses. In this way, at a junction of the first film layer and the second film layer, the direction of the light can be adjusted on the basis of a difference of the refractive indexes of the first film layer and the second film layer to increase the luminous brightness of the display panel at different viewing angles according to the requirements. Exemplarily, as shown in FIGS. 2 and 3, a first film layer 210 and a second film layer 220 are superposed on the display substrate 100, a first recess 201 defined by the first film layer 210 is opposite to the light-emitting device 101, and the first recess 201 is filled with the second film layer 220. The second film layer 220 has a refractive index greater than a refractive index of the first film layer 210. Therefore, in an area where the first recess 201 is located, with regard to light G1 emitted by the light-emitting device 101 to a side wall 211 of the first recess 201 through the first film layer 210, a refraction direction thereof upon the light entering the second film layer 220 will tend to be perpendicular to the Z-axis, that is, the light G1 tends to emerge at a front viewing angle, such that the luminous brightness of the display panel at the front viewing angle can be increased. Furthermore, light G3 at a large inclination angle, which is emitted by the light-emitting device 101 to the side wall 211 of the first recess 201 through the second film layer 220 (from an optically denser medium to an optically thinner medium), may be totally reflected at the side wall 211, so that the reflection direction of the light G3 also tends to be perpendicular to the Z-axis, that is, the light G3 tends to emerge at the front viewing angle, and thus the luminous brightness of the display panel at the front viewing angle can be further increased.

Moreover, as shown in FIG. 2, the second film layer 220 may be set to have a refractive index greater than a refractive index of a receiving layer (e.g., an encapsulation layer or the like mentioned in the following embodiments) adjacent to the lens structure of the display substrate 100, such that light G2 at an inclination angle, which is directly incident into the first recess 201, is refracted at an interface of the second film layer 220 and the display substrate 100, and a refraction angle is less than an incidence angle such that the refracted light G2 can tend to emerge at the front viewing angle, and thus the luminous brightness of the display panel at the front viewing angle can further be increased.

In at least one embodiment of the disclosure, as shown in FIG. 2, an orthographic projection of the light-emitting device 101 on the display substrate is located within an orthographic projection of the first recess 201 on the display substrate. In this way, the size (planar area) of the first recess 201 is greater than the size (planar area) of the light-emitting device 101, so that the emitting direction of the light (e.g., the light G1 and the light G3) emitted by the light-emitting device 101 in a larger range of light-emitting angles can be regulated and controlled, which is conducive to increasing the area and the amount of light emitted by the corresponding sub-pixel.

In at least one embodiment of the disclosure, an orthographic projection of an end 212, facing the display substrate 100, of the first recess 201 on the display substrate is located within an orthographic projection of an end 213, facing away from the display substrate 100, of the first recess 201 on the display substrate. In this way, a longitudinal cross-sectional shape of the first recess 201 along the Z-axis wholly tends to be an inverted trapezoid, a top side of the inverted trapezoid is the end 212 of the first recess 201 (a vertical cross section thereof) facing the display substrate 100, and a bottom side of the inverted trapezoid is the end 213 of the first recess 201 (a vertical cross section thereof) facing away from the display substrate 100, such that the obliquely incident light (e.g., the light G1 and the light G3) are collimated at a junction (the side wall 211 of the first recess 201) of the first film layer 210 and the second film layer 220, thereby increasing the luminous flux of the sub-pixels of the display panel at the front viewing angle and the luminous brightness of the display panel.

It should be understood that in this embodiment of the disclosure, the shape of the first side wall is not specifically defined if the shape of the first recess is designed to tend to be the inverted trapezoid. For example, in some embodiments, the side wall of the first recess is in a planar shape. For example, in other embodiments, as shown in FIGS. 2 and 3, the side wall 211 of the first recess 201 is in the shape of a curved surface, the curved surface protrudes toward an inner side of the first recess, that is, any point, between the end 212 and the end 213, of a cross section of the curved surface along the Z-axis is located on a side, facing the first recess 201, of a straight line defined by the end 212 and the end 213. In the above embodiment, by controlling the variation laws of the inclination angle of the side wall 211 and the inclination angle of the side wall (a curvature of the curved surface, etc.), a variation range of an emergence (reflection and/or transmission) angle of the light at the side wall 211 can be controlled to adjust the luminous fluxes at different viewing angles.

For example, in the embodiment of the disclosure, if the side wall of the first recess is in the shape of a curved surface, a surface of the first film layer 210 facing away from the display substrate 100 is smoothly connected to the curved surface, so that the emergence direction of the light at the junction of the surface and the curved surface is gradually varied, and the brightness of a display image of the display panel also changes uniformly when the different viewing angles are switched, so as to improve the display effect of the display image.

In at least one embodiment of the disclosure, the display panel may further include a black matrix. As shown in FIGS. 2 and 3, the black matrix 300 includes a plurality of openings 301 corresponding to the lens units 200, the openings 301 penetrate through the black matrix, and the orthographic projection of the light-emitting device 101 on the display substrate is located within an orthographic projection of the corresponding opening 301 on the display substrate. In this way, the luminous area of the (corresponding) sub-pixel of the display panel can be defined by the black matrix 300. Furthermore, by designing the dimensional proportion of the opening 301 of the black matrix 300 to the light-emitting device 101 and a spacing between the black matrix 300 and the light-emitting device 101, the range of the light-emitting angle (the range of a large viewing angle) of the image of the display panel can be controlled. For example, if the size of the opening 301 is constant, the smaller the spacing between the black matrix 300 and the light-emitting devices 101 is, the larger the range of the light-emitting angle of the image of the display panel is. In this description, the orthographic projection of the opening can be understood as an orthographic projection of an edge contour of the opening.

In the embodiment of the disclosure, a specific range of the above dimensional proportion is not defined. For example, in a Y-axis direction, a spacing between an orthographic projection of an edge, facing the first recess, of the black matrix on the display substrate and an orthographic projection of an edge of the end, facing the display substrate, of the first recess on the display substrate is greater than a spacing between the orthographic projection of the edge of the end, facing the display substrate, of the first recess on the display substrate and an orthographic projection of an edge of the light-emitting device on the display substrate. Specifically, the minimum distance between the end 212, facing the display substrate 100, of the side wall 211 of the first recess 201 and the edge of the light-emitting device 101 may be ⅓-½ of the minimum distance between the edge of the black matrix 300 (or the side wall of the opening 301) and an edge of the light-emitting device 101. For example, in the Y-axis direction, one end 212 of the side wall 211 and the light-emitting device 101 are spaced by a distance of 0-2 microns, and a side wall of the opening 301 and the light-emitting device 101 are spaced by a distance of 2-6 microns.

In the embodiments of the disclosure, the second film layer may be selected as the color blocking layer, and alternatively a part of the second film layer may be designed as the color blocking layer; furthermore, if a part of the second film layer is configured to be composed of the color blocking material, a distribution position of the color blocking material in the second film layer and a positional relationship thereof with the first film layer may be selected differently according to actual requirements; moreover, if the black matrix is provided, a specific position of the black matrix may be designed according to the position of the color blocking material in the second film layer. The structure of the display panel with these different options will be explained below in conjunction with different embodiments.

In some embodiments of the disclosure, as shown in FIGS. 2 and 3, the second film layer 220 is the color blocking layer, that is, the entire second film layer 220 is composed of the color blocking material, namely, the second film layer 220 serves as a color filter itself. In addition, the entire second film layer 220 has a refractive index greater than a refractive index of the first film layer 210. In this way, since the second film layer 220 of the lens structure is also equivalent to the color filter, a space reserved for designing the color filter can no longer be considered during the module design of the display panel, and thus the lightweight and thin design of the display panel is further facilitated.

If the display panel is provided with the black matrix and the second film layer is the color blocking layer, the black matrix may be configured in at least three ways, and for details, reference may be made to the display panels in the embodiments respectively shown in FIGS. 2, 4 and 5 below.

In some embodiments of the disclosure, as shown in FIGS. 2 and 3, if the second film layer 220 is the color blocking layer, the black matrix 300 may be located on a side of the first film layer 210 facing the display substrate 100, that is, the first film layer 210 covers the black matrix 300. With this design, the black matrix 300 can be construed as being embedded in the first film layer 210, and design dimensions (e.g., an area, a length in the Y-axis direction, a height in a Z-axis direction, etc.) of the side wall 211 of the first recess 201 may not be affected, that is, even though a design height of the first film layer 210 (a distance between the display substrate 100 and a surface of the first film layer facing away from the display substrate 100) is not increased, the side wall 211 can still be kept to have large enough dimensions to regulate and control incident light. Also, with this design, the arrangement of the black matrix 300 does not increase a design thickness of the display panel, and thus the lightweight and thin design of the display panel is facilitated; besides, the raising effect of the black matrix 300 is further conducive to forming the side wall 211 into the curved surface (e.g., in an arc shape) so as to ensure a light convergence effect at this side wall 211.

In the embodiments as shown in FIGS. 2 and 3, the orthographic projection (area A1) of the end 212, facing the display substrate 100, of the first recess 201 on the display substrate is located within an orthographic projection of the opening 301 on the display substrate, and the orthographic projection of the opening 301 on the display substrate is within the orthographic projection (area A2) of the end 213, facing away from the display substrate 100, of the first recess 201 on the display substrate. In this way, the incident light at a large inclination angle is not blocked by the black matrix 300 when being incident to the side wall 211; in addition, the black matrix 300 can also block the incident light at the large inclination angle that is incident to an area outside the first recess 201 (outside an active area of the lens unit 200), such that a transmission direction of emergent light of the display panel is regulated and controlled by the lens structure.

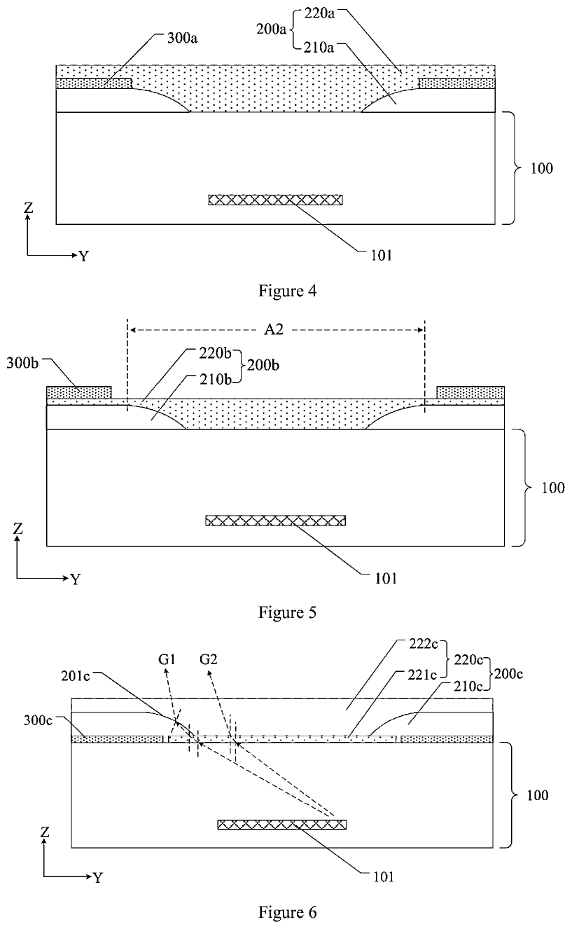

In other embodiments of the disclosure, as shown in FIG. 4, if the second film layer 220 is the color blocking layer, a black matrix 300a is located between a first film layer 210a and a second film layer 220a.

In the embodiment shown in FIG. 4, the orthographic projection of the end, facing away from the display substrate, of the first recess on the display substrate may coincide with the corresponding opening of the black matrix 300a. That is, it can be understood that the orthographic projection of the end, facing away from the display substrate, of the first recess may coincide with the orthographic projection of the opening on the display substrate, namely, in the area where the first recess is located, an edge of a surface of the first film layer 210a facing away from the display substrate 100 coincides with an edge of the black matrix 300a. In this way, the incident light at the large inclination angle may not be blocked by the black matrix 300a when emerging from the side wall of the first recess; in addition, the black matrix 300a may also block the incident light at the large inclination angle that is incident to an area outside the first recess (outside an active area of a lens unit 200a), so that the transmission direction of emergent light of the display panel is regulated and controlled by the lens structure.

In still other embodiments of the disclosure, as shown in FIG. 5, if a second film layer 220b of a lens unit 200b is the color blocking layer, a black matrix 300b is located on a side of the second film layer 220b facing away from the display substrate 100.

In the embodiment shown in FIG. 5, the orthographic projection (area A2) of the end, facing away from the display substrate 100, of the first recess on the display substrate is located within the opening. The black matrix 300b is separated from a first film layer 210b by the second film layer 220b, and if the size of the opening is greater than the size of the first recess, the black matrix 300b can be prevented from blocking the light that is regulated and controlled by the side wall of the first recess but is emergent at the large inclination angle.

For example, in the display panel shown in FIG. 5, compared with the display panels shown in FIGS. 3 and 4, a distance between an edge of the black matrix 300b and an edge of the first recess facing the display substrate 100 has a greater difference than a distance between the edge of the first recess facing the display substrate 100 and the edge of the light-emitting device 101 in the Y-axis direction, in order to prevent the light emerging from the light-emitting device 101 from being blocked by the black matrix 300b.

It should be noted that in some embodiments of the disclosure, the dimensions of the black matrix 300b in the display panel as shown in FIG. 5 may also be modified such that the orthographic projection of the end, facing away from the display substrate 100, of the first recess on the display substrate may coincide with the opening of the black matrix, that is, in the area where the first recess is located, an edge of a surface of the first film layer 210b facing away from the display substrate 100 coincides with the edge of the black matrix 300b.

The second film layer being the color blocking layer is as already described above, and the case where a part of the second film layer is designed as the color blocking layer will be described below.

In other embodiments of the disclosure, as shown in FIG. 6, a second film layer 220c includes a first sub-film layer 221c and a second sub-film layer 222c, and a first recess 201c is designed to penetrate through the first sub-film layer 221c. The first sub-film layer 221c is a color blocking layer to serve as the color filter. The second sub-film layer 222c is located on a side of the first sub-film layer 221c facing away from the display substrate 100, and the second sub-film layer 222c has a refractive index greater than a refractive index of a first film layer 210c. In this way, the material selection of a part of the second film layer 220c (the second sub-film layer 222c) having a high refractive index is not defined by the color blocking material, an excessively large design area of the color blocking material is prevented from causing impurity doping of the color blocking material between the different sub-pixels, the problem of color cast of the different sub-pixels is then solved, and the effect of image display is thus improved.

For example, as shown in FIG. 6, the second sub-film layer 222c has a refractive index greater than a refractive index of the first sub-film layer 221c. Thus, at a junction of the first sub-film layer 221c and the second sub-film layer 222c, the obliquely incident light (e.g., light G2) tends to emerge in the Z-axis direction after being refracted, and thus a light output rate at the front viewing angle is further improved.

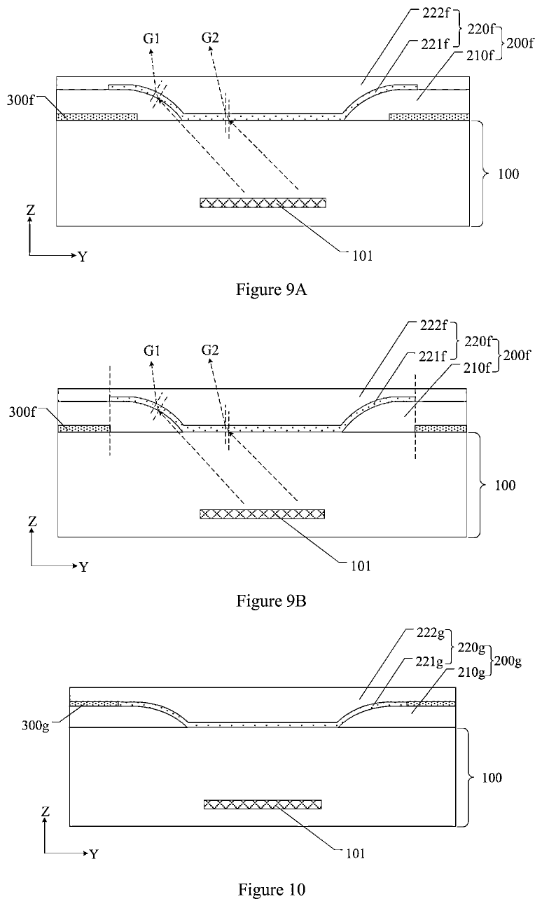

It should be noted that in the embodiments of the disclosure, the second film layer includes the first sub-film layer and the second sub-film layer, and if only the first sub-film layer is the color blocking layer, the first sub-film layer may optionally be arranged below the first film layer (e.g., the embodiments shown in FIGS. 6, 7A, 7B, and 8) or may optionally be arranged above the first film layer (e.g., the embodiments shown in FIG. 9A, FIG. 9B and FIGS. 10 to 13).

In some embodiments of the disclosure, as shown in FIG. 6, if the second film layer 220c includes the first sub-film layer 221c and the second sub-film layer 222c, the first sub-film layer 221c is located between the display substrate 100 and the first film layer 210c, and an orthographic projection of the first recess 201c on the display substrate is located within an orthographic projection of the first sub-film layer 221c on the display substrate such that the first film layer 210c covers an edge part of the first sub-film layer 221c. In this way, it can be ensured that the light G1 incident to a side wall of the first recess 201c at the large inclination angle passes through the first sub-film layer 221c (the color blocking material) to ensure the purity of a light-emitting color of the sub-pixel. Furthermore, in this design, the first sub-film layer 221c has a high planarization degree, which is conducive to ensuring the continuity of the first sub-film layer 221c in the process of forming the color blocking material, to further ensure the purity of the light-emitting color of the sub-pixel.

For example, as shown in FIG. 6, the first sub-film layer 221c may be further designed to have a refractive index less than a refractive index of the first film layer 210c. In this way, the first sub-film layer 221c, the first film layer 210c and the second sub-film layer 222c are sequentially superposed on the display substrate 100, and the refractive indexes of the three layers are increased successively, which is more conducive to increasing the light output rate of the light at the front viewing angle. Exemplarily, the light G1 at the large inclination angle first passes through the first sub-film layer 221c and is then incident to the first film layer 210c and further incident to the side wall of the first recess 201c, and a refraction angle of the light G1 is less than an incidence angle at a junction of the first sub-film layer 221c and the first film layer 210c (from optically thinner to optically denser), such that the light G1 has been collimated once before reaching the side wall of the first recess 201c, and the light G1 can be collimated again when the light G1 passes through the side wall of the first recess 201 (from optically thinner to optically denser); moreover, the obliquely incident light G2 (at a smaller inclination angle) first passes through the first sub-film layer 221c and is then incident to the second film layer 220c (from optically thinner to optically denser), and a refraction angle of the light G2 is less than the incidence angle, such that the light G2 is collimated once at the junction of the first sub-film layer 221c and the second sub-film layer 222c. It can be seen from the above description that the collimation degree of the light passing through the lens unit is further improved with the above design, and thus the light output amount of the display panel at the front viewing angle is increased.

If the display panel is provided with the black matrix, the first sub-film layer is located between the display substrate and the first film layer and the first sub-film layer is configured as the color blocking layer, the black matrix may be configured in at least three ways, and for details, reference may be made to the display panels in the embodiments respectively shown in FIGS. 6, 7A, 7B and 8.

In some embodiments of the disclosure, as shown in FIG. 6, the black matrix 300c is located on a side of the second film layer 220c facing the display substrate 100 to be in the same layer as the first sub-film layer 221c, that is, the first film layer 210c covers the black matrix 300c. With this design, the black matrix 300c can be construed as being embedded in the first film layer 210c, and design dimensions of the side wall of the first recess 201c may not be affected, that is, even though a design height of the first film layer 210c (a distance between the display substrate 100 and a surface of the first film layer facing away from the display substrate 100) is not increased, the side wall can still be kept to have large enough dimensions to regulate and control the incident light. Also, with this design, the arrangement of the black matrix 300c does not increase the design thickness of the display panel, and thus the lightweight and thin design of the display panel is facilitated.

For example, if the black matrix is in the same layer as the first sub-film layer, an edge of the black matrix can be interfaced with an edge of the first sub-film layer to prevent the light from exiting through a gap between the black matrix and the first sub-film layer. For example, in an actual process, the connected edges of the black matrix and the first sub-film layer may overlap to avoid the gap between the black matrix and the first sub-film layer due to process precision, etc.

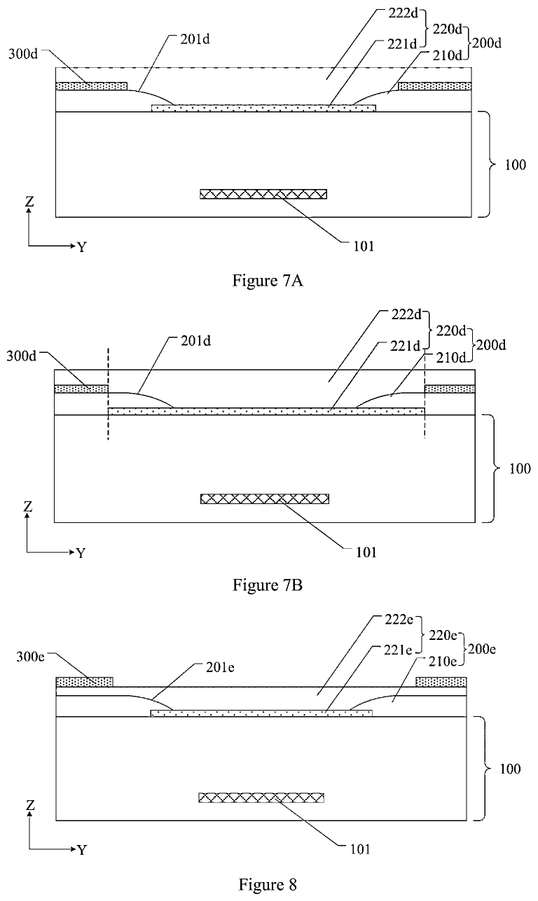

In other embodiments of the disclosure, as shown in FIGS. 7A and 7B, a black matrix 300d is located between a first film layer 210d and a second sub-film layer 222d of a second film layer 220d, that is, the black matrix 300d is embedded in a layer structure where a lens unit 200d is located, and the first sub-film layer 221d, the first film layer 210d, the black matrix 300d and the second sub-film layer 222d are sequentially superposed on the display substrate 100.

In the embodiment shown in FIG. 7A, an orthographic projection of a first recess 201d on the display substrate is located within an opening of the black matrix 300d, and an orthographic projection of the first sub-film layer 221d on the display substrate coincides with the opening, that is, in an area where the first recess 201d is located, an edge of a surface, facing away from the display substrate 100, of the first film layer 210d of the lens unit 200d coincides with an edge of the black matrix 300d. In this way, the incident light at the large inclination angle is not blocked by the black matrix 300d when emerging from a side wall of the first recess 201d; in addition, the black matrix 300d can also block the incident light at the large inclination angle that is emitted to an area outside the first recess 201d, so that the transmission direction of the emergent light of the display panel is regulated and controlled by the lens structure. In this description, being located within the opening may be understood as being located within an area corresponding to the opening.

For example, in the embodiment shown in FIG. 7B, the orthographic projection of the first sub-film layer 221d on the display substrate coincides with the opening, that is, the edge of the black matrix 300d for defining the opening is aligned with an edge of the first sub-film layer 221d. This design can further increase the blocking area of the first sub-film layer 221d, such that the light emerging from the light-emitting device passes through the first sub-film layer 221d as much as possible and light leakage is further eliminated. For example, an orthographic projection of the first recess 201d on the display substrate is further designed to be located within the opening of the black matrix 300d. For example, in the Y-axis direction, if a spacing between the first film layer 210d (or an edge of the end of the first recess facing the display substrate 100) and the light-emitting device 101 is 1.5 microns, a spacing from the edge of the black matrix 300d for defining the opening and the edge of the first sub-film layer 221d to the light-emitting device 101 is 6 microns.

In a preparation process of the display panel as shown in FIG. 7A and FIG. 7B, after the first sub-film layer 221d is prepared on the display substrate 100, the first film layer 210d may be prepared by means of an optical adhesive, where the optical adhesive is directly patterned by means of a photoetching process to obtain the first film layer 210d having the first recesses, the black matrix 300d is then prepared on the first film layer 210d, and the first recesses are later filled and leveled up by means of ink-jet printing or the like to form the second sub-film layer 222d having a high refractive index.

In still other embodiments of the disclosure, as shown in FIG. 8, a black matrix 300e is located on a side of a second film layer 220e facing away from the display substrate 100, that is, the black matrix 300e is located on a layer structure where a lens unit 200e is located, and a first sub-film layer 221e, a first film layer 210e, a second sub-film layer 222e and the black matrix 300e are sequentially superposed on the display substrate 100.

For example, in the embodiment shown in FIG. 8, an orthographic projection of a first recess 201e on the display substrate is located within an opening of the black matrix 300e, and an orthographic projection of the first sub-film layer 221e on the display substrate is located within the opening. The black matrix 300e is separated from the first film layer 210e by the second sub-film layer 222e, and if the size of the opening is greater than the size of the first recess 201e, the black matrix 300e can be prevented from blocking the light that is regulated and controlled by the side wall of the first recess 201e but is emergent at the large inclination angle.

It should be noted that in some embodiments of the disclosure, the dimensions of the black matrix 300e in the display panel as shown in FIG. 8 may also be modified such that an orthographic projection of an end, facing away from the display substrate 100, of the first recess 201e on the display substrate may coincide with the opening of the black matrix, that is, in an area where the first recess 201e is located, an edge of a surface, facing away from the display substrate 100, of the first film layer 210e coincides with an edge of the black matrix 300e.

The above description illustrates that the second film layer includes the first sub-film layer and the second sub-film layer and the first sub-film layer including the color blocking material is arranged below the first film layer, the following description will explain that the first sub-film layer including the color blocking material is arranged on the first film layer.

In other embodiments, as shown in FIG. 9A, if a second film layer 220f includes a first sub-film layer 221f and a second sub-film layer 222f, the first sub-film layer 221f is located on a side of the first film layer 210f facing away from the display substrate 100 and covers the first recess; and a part of the first sub-film layer 221f covering the first recess is conformal with the first recess to form a second recess, and the second recess is filled with at least part of the second sub-film layer 222f. In this way, the first recess is filled with both the first sub-film layer 221f and the second sub-film layer 222f, and the first film layer 210f, the first sub-film layer 221f and the second sub-film layer 222f are sequentially superposed on the display substrate 100. In these embodiments, it can be ensured that the light G1 incident to the side wall of the first recess at the large inclination angle passes through the first sub-film layer 221f (the color blocking material) to ensure the purity of a light-emitting color of the sub-pixel; moreover, the first sub-film layer 221f covers the side wall of the first recess, such that the light emerging from the first recess and located at a junction of the first film layer 210f and the second film layer 220f all passes through the first sub-film layer 221f, and thus the purity of the light-emitting color of the sub-pixel can be ensured.

It should be noted that surface shapes of the two “conformal” objects are substantially the same in category and may have a size difference somewhat, that is, if one surface is a recess, the other surface is also a recess, and the upper recess (formed in a subsequent technological process) is relatively smaller in size. For example, if the part of the first sub-film layer 221f covering the first recess is conformal with the first recess, a surface, facing away from the display substrate, of the part of the first sub-film layer 221f covering the first recess has substantially the same shape as a surface (including the bottom and a side wall) of the first recess facing away from the display substrate, and the recess formed by the part of the first sub-film layer 221f covering the first recess is less than the first recess in size.

For example, as shown in FIG. 9A, the first sub-film layer 221f may be further designed to have a refractive index greater than a refractive index of the first film layer 210f. In this way, if the first film layer 210f, the first sub-film layer 221f and the second sub-film layer 222f are sequentially superposed on the display substrate 100, the refractive indexes of the three layers are increased successively, which is more conducive to increasing the light output rate of the light at the front viewing angle. Exemplarily, the light G1 at the large inclination angle first passes through the first film layer 210f and is then incident to the side wall of the first recess and further incident to the second sub-film layer 222f through the first sub-film layer 221f, and the refraction angle of the light G1 is less than the incidence angle at a junction of the first sub-film layer 221f and the first film layer 210f (from optically thinner to optically denser), such that the light G1 has been collimated once at the side wall of the first recess, and later the light G1 can be collimated again when the light G1 passes through a junction of the first sub-film layer 221f and the second sub-film layer 222f (from optically thinner to optically denser); moreover, the obliquely incident light G2 (at a smaller inclination angle) first passes through the first sub-film layer 221f and is then incident to the second film layer 220f (from optically thinner to optically denser), and the refraction angle of the light G2 is less than the incidence angle, such that the light G2 is collimated once at the junction of the first sub-film layer 221f and the second sub-film layer 222f. It can be seen from the above description that the collimation degree of the light passing through the lens unit is further improved with the above design, and thus the light output amount of the display panel at the front viewing angle is increased.

For example, as shown in FIG. 9A, if the first sub-film layer 221f is located on the side of the first film layer 210f facing away from the display substrate 100, the first sub-film layer 221f may be further configured to extend to a surface of the first film layer 210f facing away from the display substrate 100, that is, the orthographic projection of the end, facing away from the display substrate 100, of the first recess on the display substrate is located within an orthographic projection of the first sub-film layer 221f on the display substrate. In this way, in an actual process of preparing the display panel, it can be ensured that the requirement for process precision is reduced if the first sub-film layer 221f (the color blocking material) can cover the side wall of the first recess, so as to reduce the difficulty in the process of preparing the display panel.

For example, as shown in FIG. 9A, if the first sub-film layer 221f may be further configured to extend to the surface of the first film layer 210f facing away from the display substrate 100, the thickness of the part of the first sub-film layer 221f located in the first recess is greater than the thickness of a part thereof located outside the first recess. In this way, the second sub-film layer 222f being excessively thick due to the arrangement of the first sub-film layer 221f can be avoided, which is conducive to the lightweight and thin design of the display panel.

If the display panel is provided with the black matrix and the first sub-film layer including the color blocking material is located between the first film layer and the second sub-film layer (equivalent to being located on the side of the first film layer facing away from the display substrate), the black matrix can be configured in at least three ways, and for details, reference may be made to the display panels in the embodiments respectively shown in FIGS. 9A, 9B, 10 and 11.

In some embodiments of the disclosure, as shown in FIG. 9A, the black matrix 300f is located on the side of the first film layer 210f facing the display substrate 100, that is, the first film layer 210f covers the black matrix 300f. With this design, the black matrix 300f can be construed as being embedded in the first film layer 210f, and design dimensions of the side wall of the first recess may not be affected, that is, even though a design height of the first film layer 210f (a distance between the display substrate 100 and the surface of the first film layer facing away from the display substrate 100) is not increased, the side wall can still be kept to have large enough dimensions to regulate and control the incident light. Also, with this design, the arrangement of the black matrix 300f does not increase the design thickness of the display panel, and thus the lightweight and thin design of the display panel is facilitated.

For example, as shown in FIG. 9A, the size of an opening of the black matrix 300f may be set to be greater than the size of the end of the first recess facing the display substrate 100 and less than the size of the end of the first recess facing away from the display substrate 100, that is, the opening of the black matrix 300f is located within the orthographic projection of the first sub-film layer on the display substrate, and the orthographic projection of the end, facing the display substrate, of the first recess on the display substrate is located within the opening. In this way, the incident light (e.g., the light G1) at the large inclination angle cannot be blocked by the black matrix 300f when being incident to the side wall of the first recess; in addition, the black matrix 300f can also block the incident light at the large inclination angle that is incident to the area outside the first recess (outside an active area of the lens unit 200f), so that the transmission direction of the emergent light of the display panel is regulated and controlled by the lens structure.

For example, as shown in FIG. 9B, the size of the opening of the black matrix 300f may also be set to be greater than the size of the end of the first recess facing the display substrate 100 and greater than the size of the end of the first recess facing away from the display substrate 100, and the opening of the black matrix 300f coincides with the orthographic projection of the first sub-film layer on the display substrate, that is, the edge of the first sub-film layer is aligned with the edge of the black matrix for defining the opening.

In other embodiments of the disclosure, as shown in FIG. 10, a black matrix 300g is located between a first film layer 210g and a second sub-film layer 222g of a second film layer 220g of a lens unit 200g to be in the same layer as a first sub-film layer 221g, that is, the black matrix 300g is embedded in a layer structure where the lens unit 200g is located, and the first film layer 210g, the first sub-film layer 221g, the black matrix 300g and the second sub-film layer 222g are sequentially superposed on the display substrate 100.

As shown in FIG. 10, an orthographic projection of the first sub-film layer 221g on the display substrate may be further designed to be located within the opening. For example, the black matrix 200g may be further designed to be interfaced with an edge of the first sub-film layer 221g to prevent the light from exiting through a gap between the black matrix 300g and the first sub-film layer 221g. For example, in an actual process, connected edges of the black matrix 300g and the first sub-film layer 221g may overlap to avoid the gap between the black matrix and the first sub-film layer due to the process precision, etc.

For example, in the embodiment shown in FIG. 10, the orthographic projection of the first sub-film layer 221g on the display substrate coincides with the opening, that is, an edge of the black matrix 300g for defining the opening is aligned with an edge of the first sub-film layer 221g. This design can further increase the blocking area of the first sub-film layer 221g, such that the light emerging from the light-emitting device passes through the first sub-film layer 221g as much as possible, and light leakage is further eliminated. For example, an orthographic projection of a first recess 201g on the display substrate is further designed to be located within an opening of the black matrix 300g. For example, in the Y-axis direction, if a spacing between the first film layer 210g (or an edge of the end of the first recess facing the display substrate 100) and the light-emitting device 101 is 1.5 microns, a spacing from the edge of the black matrix 300g for defining the opening and the edge of the first sub-film layer 221g to the light-emitting device 101 is 6 microns.

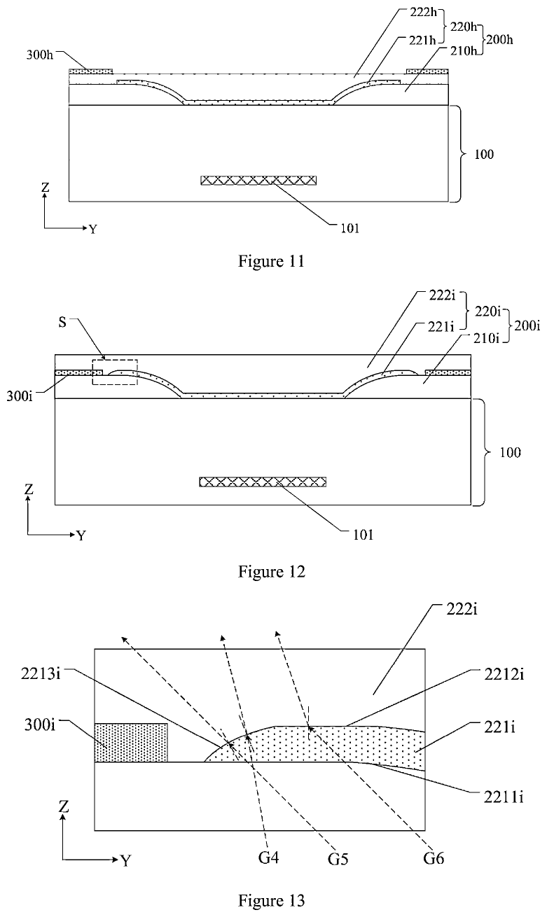

In still other embodiments of the disclosure, as shown in FIG. 11, a black matrix 300h is located on a side of a second film layer 220h facing away from the display substrate 100, that is, the black matrix 300h is located on a layer structure where a lens unit 200h is located, and a first film layer 210h, a first sub-film layer 221h, a second sub-film layer 222h and the black matrix 300h are sequentially superposed on the display substrate 100.

In the embodiment shown in FIG. 11, the orthographic projection of the first recess on the display substrate is located within the opening, and the orthographic projection of the first sub-film layer on the display substrate is located within the opening. The black matrix 300h is separated from the first film layer 210h by the second sub-film layer 222h, and if the size of the opening is greater than the size of the first recess, the black matrix 300h can be prevented from blocking the light that is regulated and controlled by the side wall of the first recess but is emergent at the large inclination angle.

It should be noted that in some embodiments of the disclosure, the dimensions of the black matrix 300h in the display panel as shown in FIG. 11 may also be modified such that the orthographic projection of the end, facing away from the display substrate 100, of the first recess on the display substrate may coincide with the opening of the black matrix, that is, in the area where the first recess is located, an edge of a surface, facing away from the display substrate 100, of the first film layer 210h coincides with an edge of the black matrix 300h.

In the embodiments of the disclosure, if the first sub-film layer covers the side wall of the first recess, the edge part of the first sub-film layer may be modified such that part of the light at the large emergence angle can have a larger emergence angle while the light output rate of the light at the front viewing angle is increased, allowing the display panel to have a larger viewing angle and increasing the brightness of the display image at the large viewing angle thereof.

Exemplarily, as shown in FIGS. 12 and 13, a first film layer 210i, a first sub-film layer 221i and a second sub-film layer 222i in a lens unit 200i are sequentially superposed on the display substrate 100; the first sub-film layer 221i includes a first main surface 2211i facing the display substrate 100, a second main surface 2212i facing away from the display substrate, and a first side surface 2213i for connecting the first main surface 2211i and the second main surface 2212i; and the first side surface 2213i is a curved surface that protrudes toward a side of the first sub-film layer facing away from the first recess. At the first side surface 2213i, light G4 and light G5, which are partially incident at a large inclination angle, are incident from the first sub-film layer 221i to the second sub-film layer 222i (e.g., from optically thinner to optically denser), an incidence angle thereof is greater than a refraction angle, and according to the incidence angle and an inclination degree (a tangent or normal angle at an incidence position) of the side wall of the first recess, the inclination angle of the light G4 is larger, that is, the light emerges at a larger inclination angle, while the inclination angle of the light G5 becomes smaller, and the light will be collimated. In addition, light G6, which is incident to the second main surface 2212i at a larger inclination angle, is collimated due to the fact that the incidence angle thereof is greater than the refraction angle. Moreover, the light G5 and the light G6 are parallel light beams because the light G5 emerges from the inclined first side surface 2213i, and after the light G5 and the light G6 enter the second sub-film layer 222i, the inclination angle of the light G5 is greater than the inclination angle of the light G6, that is, the first side surface 2213i can also reduce the collimation degree of part of the light (e.g., the light G5) incident at the large inclination angle, such that the display image of the display panel still has a relatively higher brightness at the large inclination angle.

For example, the first side surface 2213i and the second main surface 2212i may be further designed to be connected smoothly, such that the emergence direction of the light at a junction of the first side surface 2213i and the second main surface 2212i may change gradually, and the brightness of the display image of the display panel also changes uniformly during the switching of different viewing angles to improve the display effect of the display image.

For example, as shown in FIGS. 12 and 13, if the first side surface 2213i is designed as a curved surface and the black matrix 300i is configured to be in the same layer as the first sub-film layer 221i, the black matrix 300i may be designed to be spaced by a certain distance from the first sub-film layer 221i, to prevent the black matrix 300i from blocking part of the light emerging at the large inclination angle.

As described above, if the first sub-film layer covers the side wall of the first recess, how to modify the edge part of the first sub-film layer is described to increase the brightness of the display image of the display panel at the large viewing angle. Similarly, the second sub-film layer can also use a similar design to further increase the brightness of the display image of the display panel at the large viewing angle. This design will be described below in conjunction with several specific embodiments.

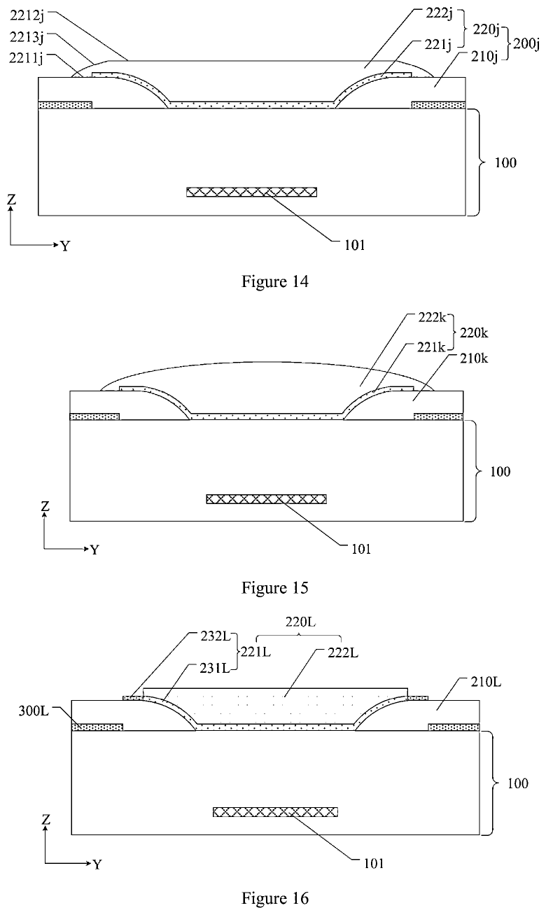

In some embodiments of the disclosure, as shown in FIG. 14, a first film layer 210j, a first sub-film layer 221j and a second sub-film layer 222j in a lens unit 200j are sequentially superposed on the display substrate 100; the second sub-film layer 222j includes a third main surface 2211j facing the display substrate 100, a fourth main surface 2212j facing away from the display substrate, and a second side surface 2213j for connecting the third main surface 2211j and the fourth main surface 2212j; and the second side surface 2213j is a curved surface that protrudes toward the side of the second sub-film layer facing away from the first recess. For the principle of regulating and controlling the incident light by the second side surface 2213j, reference can be made to the relevant description of the first side surface in the embodiments described above, which will not be described in detail herein. It should be noted that, as the light emerges from the second side surface 2213j, whether entering an optically denser medium or an optically thinner medium, the light emerging from the second side surface 2213j can have a relatively larger inclination angle compared with the light emerging from the fourth main surface 2212j, to ensure the brightness of the display image of the display panel at the large inclination angle.

In the embodiments of the disclosure, a fourth surface of the second sub-film layer is not defined in shape, and may be designed as a planar surface or as a curved surface, which will be described below in different embodiments.

For example, in some embodiments of the disclosure, as shown in FIG. 14, the fourth main surface of the second sub-film layer 222j is a planar surface.

For example, in other embodiments of the disclosure, as shown in FIG. 15, a fourth main surface of a second sub-film layer 222k is a curved surface that protrudes toward the side facing away from the first recess. In this way, a second film layer 220k is equivalent to a convex lens, the light-emitting angle of the light at the large viewing angle can be increased while ensuring the amount of the light output at the front viewing angle. Also, the amount of the light output at the large viewing angle is increased to widen a viewing angle range of the display image and increase the display brightness at each viewing angle.

For example, whether the fourth main surface of the second sub-film layer is configured as the planar surface or the curved surface, the second side surface of the second sub-film layer may further be designed to be smoothly connected to the fourth main surface, such that the emergence direction of the light at a junction of the second side surface and the fourth main surface may change gradually, and the brightness of the display image of the display panel also changes uniformly during the switching of different viewing angles to improve the display effect of the display image.

In yet other embodiments of the disclosure, as shown in FIG. 16, a first sub-film layer 221L of a second film layer 220L is configured to include two parts 231L and 232L, a part (configured as the first part 231L) of the first sub-film layer 221L located in the first recess has a refractive index greater than a refractive index of a part (configured as the second part 232L) located outside the first recess, and a second sub-film layer 222L covers the first part 231L but not covers the second part 232L, that is, an orthographic projection of the part, located outside the first recess, of the first sub-film layer 221L on the display substrate is located outside an orthographic projection of the second sub-film layer 222L on the display substrate. In this way, a structure composed of the first part 231L and the second sub-film layer 222L can still collimate incident light, and for a principle of the structure, reference can be made to the relevant description in the embodiments described above, which will not be described in detail herein; in addition, at a position where the second part 232L is located, the light incident at a large inclination angle can emerge at a larger inclination angle or be collimated to a lesser extent, to ensure the brightness of the display image of the display panel at the large viewing angle.

For example, as shown in FIG. 16, the first part 231L may be further designed to have a refractive index less than a refractive index of the second sub-film layer 222L, and the second part 232L has a refractive index less than a refractive index of the first film layer 210L. In this way, at the position where the second part 232L is located, the light incident at the large inclination angle can emerge at a larger inclination angle, which can widen the viewing angle range of the display panel, and can also increase the brightness of the display image of the display panel at the large viewing angle.

For example, as shown in FIG. 16, the larger a distance is between the part, outside the first recess, of the first sub-film layer and the first recess, the smaller the refractive index is. In this way, at the position where the second part 232L is located, the light incident at a large inclination angle also emerges at a larger inclination angle, so that the viewing angle range of the display panel is further widened, and the brightness of the display image of the display panel at the large viewing angle can further be increased.

It should be noted that in some embodiments of the disclosure, the first recess may be configured to penetrate through the first film layer, and for details, reference may be made to the structures of the display panels in the various embodiments shown in FIGS. 2-16; furthermore, in other embodiments of the disclosure, if a part composed of the color blocking material of the second film layer covers the first film layer, the first recess may be configured to not penetrate through the first film layer, and the first recess is filled with at least part of the second film layer, that is, the part of the second film layer located in the first recess is separated from the display substrate by the first film layer, so that the color blocking material (e.g. a dye) in the second film layer may be separated from the display substrate by the first film layer to prevent the color blocking material from intruding into the interior of the display substrate and to prevent a process of forming the color blocking material from damaging the display substrate (e.g., a third inorganic layer 143 below, which has a smaller thickness).

The structure of the display panel will be explained below in conjunction with some specific embodiments if the first recess is configured to not penetrate through the first film layer.

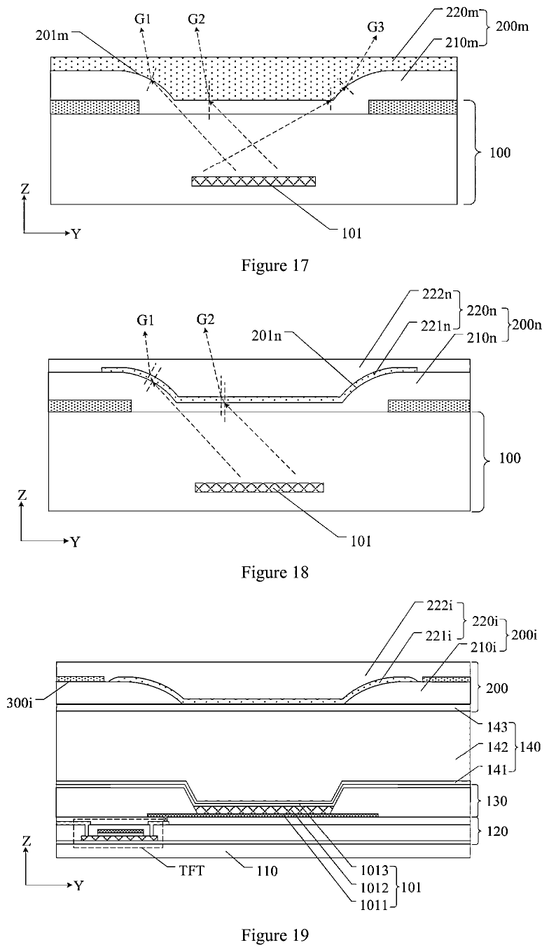

For example, in some embodiments of the disclosure, the display panel as shown in FIG. 2 may be modified to obtain a display panel as shown in FIG. 17. As shown in FIG. 17, a first film layer 210m of a lens unit 200m is provided with a first recess 201m, and the bottom of the first recess 201m is a part of a surface of the first film layer 210m facing away from the display substrate 100. A second film layer 220m is a color blocking layer, and the first recess 201m is filled with a part of the second film layer. It should be noted that the display panels shown in FIGS. 4 and 5 may also be modified similarly.

For example, in other embodiments of the disclosure, the display panel as shown in FIG. 9A may be modified to obtain a display panel as shown in FIG. 18. As shown in FIG. 18, a first film layer 210n of a lens unit 200n is provided with a first recess 201n, and the bottom of the first recess 201n is a part of a surface of the first film layer 210n facing away from the display substrate 100. A first sub-film layer 221n and a second sub-film layer 222n of the second film layer 220n are sequentially superposed on the first film layer 210n and cover the first recess 201n, and the first sub-film layer 221n including the color blocking material is completely separated from the display substrate 100 by the first film layer 210n. It should be noted that the display panels shown in FIGS. 10-16 may also be modified similarly.

In the embodiments of the disclosure, the structure of the display substrate is not defined and may be designed according to actual requirements. A display substrate is exemplified below to describe an arrangement relationship of the display substrate and the lens structure.

As shown in FIG. 19, the display substrate may include an array substrate, a display function layer 130 and a receiving layer (e.g., the third inorganic layer 143 described below).

For example, the array substrate may include a base substrate 110 and a driving circuit layer 120. The driving circuit layer 120 may include a pixel driving circuit, and in the sub-pixel corresponding to each light-emitting device 101, the pixel driving circuit may include a plurality of transistors (TFTs), capacitors, etc., for example, they are formed in multiple forms of, for example, 2T1C (i.e., two transistors (TFTs) and one capacitor (C)), 3TIC or 7TIC. The pixel driving circuit is connected to the light-emitting device 101 to control an on-off state and the luminous brightness of the light-emitting device 101.

For example, the display function layer 130 is located on a side of the array substrate facing the lens structure (including the lens units 200), and includes light-emitting devices 101 arranged in an array. The light-emitting device 101 includes an anode 1011, a light-emitting functional layer 1012 and a cathode 1013 that are sequentially superposed on the array substrate, and the light-emitting functional layer 1012 includes at least a light-emitting layer and may further include functional film layers for carriers (holes and electrons), such as an injection layer, a transport layer and a blocking layer.

For example, the receiving layer is on a side of the display function layer facing the lens structure and covers the display function layer 130.

For example, in some embodiments of the disclosure, the receiving layer may be an encapsulation layer. For example, the encapsulation layer is a single-layer structure.

For example, in some embodiments of the disclosure, the display function layer 130 is covered by the encapsulation layer, the encapsulation layer may include a first inorganic layer 141, a second organic layer 142 and a third inorganic layer 143 that are sequentially superposed on the display function layer 130, and the third inorganic layer 143 may serve as the receiving layer. For example, the materials of the first inorganic layer 141 and the third inorganic layer 143 may include inorganic materials such as silicon nitride, silicon oxide and silicon oxynitride, and the inorganic materials have a high density and can prevent the intrusion of water, oxygen and the like; for example, the material of the second organic layer 142 may be a polymer material containing a desiccant, a polymer material capable of blocking water vapor, or the like. For example, a polymer resin and the like can planarize the surface of the display panel and relieve a stress of the first inorganic layer 141 and the third inorganic layer 143, and the second organic layer 142 may further include a water absorbent material, such as a desiccant, to absorb water, oxygen or other substances intruding into the interior. The encapsulation layer 140 can block the color blocking material included in the lens unit 200 and thus avoid undesirable effects such as a poor efficiency of light excitation or even a light excitation failure because of the color blocking material intruding into the light-emitting device 101.

In at least one embodiment of the disclosure, if the lens structure is arranged on a surface of the encapsulation layer, at least a second film layer in a light-transmitting unit may be set to have a refractive index greater than a refractive index of the encapsulation layer (e.g., the third inorganic layer), to further enhance a light collimation effect and increase the display brightness of the display panel at the front viewing angle.

For example, the first film layer in the light-transmitting unit may also be set to have a refractive index greater than a refractive index of the encapsulation layer (e.g., the third inorganic layer), to further enhance the light collimation effect; alternatively, the first film layer in the light-transmitting unit is set to have a refractive index less than the refractive index of the encapsulation layer (e.g., the third inorganic layer), to further enhance a light divergence effect and increase the light emission rate at the large viewing angle.

In addition, the encapsulation layer will have a large thickness if this layer includes an organic layer, and if the lens structure is directly arranged on the encapsulation layer, at least part of the lens structure can be embedded in the encapsulation layer to further thin the display panel and reduce the weight thereof.

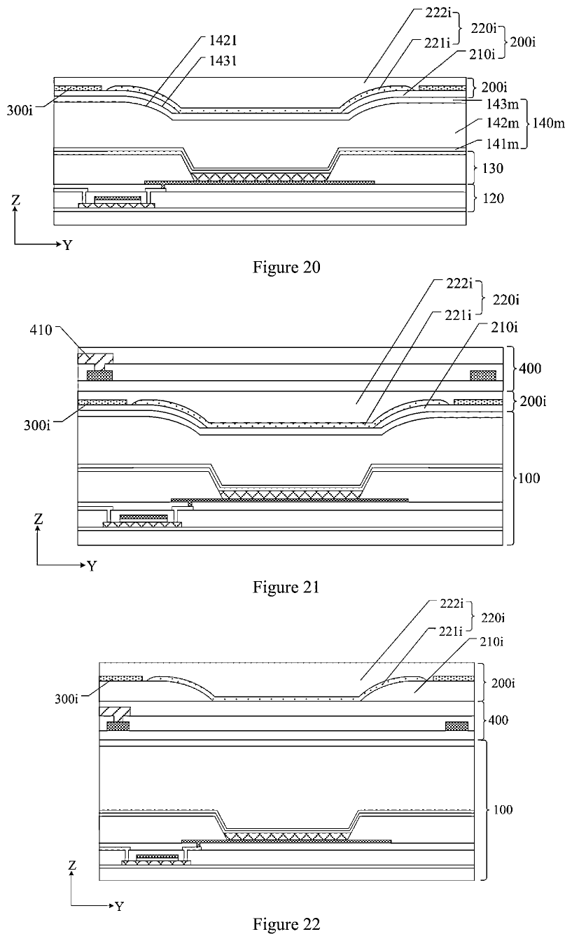

For example, in at least one embodiment of the disclosure, as shown in FIG. 20, in the process of preparing an encapsulation layer 140m, a second organic layer 142m is prepared (e.g., by means of ink-jet printing, coating, etc.) on a first inorganic layer 141m after the first inorganic layer 141m is deposited on the display function layer 130, a third recess 1421 corresponding to the light-emitting device is then formed on a surface of the second organic layer 142m by means of imprinting or etching (e.g., photoetching), etc., an inorganic material is later deposited (e.g., by means of a CVD process) on the second organic layer 142m formed with the third recess 1421 to form a third inorganic layer 143m, and the third inorganic layer 143m has a small thickness to be conformal with the surface of the second organic layer 142m, such that a fourth recess 1431 corresponding to the third recess 1421 is also formed in the third inorganic layer 143m. The bottom of the fourth recess 1431 may be configured to receive the second film layer of the lens unit 200m when the lens structure is prepared, and a side wall of the fourth recess 1431 may correspond to a side wall of the first recess of the lens unit 200i. In this way, a part of the lens unit 200i facing the display substrate is embedded in the encapsulation layer 140m, such that the design thickness of the display panel is further decreased.

It should be noted that in the embodiment shown in FIG. 20, the first recess, the third recess and the fourth recess are conformal.

It should be noted that, in the actual preparation process, the first recess may be set to have a relatively larger size, and the complete lens unit is prepared in the first recess, such that the lens unit is completely embedded in the encapsulation layer, that is, a distance between the base substrate and a surface of the lens unit facing away from the display panel is not greater than a distance between the base substrate and a part of a surface of the third inorganic layer located outside the first recess. In this way, the thickness of the display panel is not additionally increased due to the arrangement of the lens structure; moreover, the first recesses spaced apart from each other allow the lens units to be spaced apart by the encapsulation layer, thus reducing the risk of a mixture of the color blocking materials in the lens units.

In at least one embodiment of the disclosure, as shown in FIG. 21, the display panel may further include a touch structure layer 400 to provide a touch function. The touch structure layer 400 is located on the light-emitting side of the display substrate 100, the touch structure layer 400 includes a touch electrode 410, the touch electrode 410 may include a plurality of first electrodes arranged in parallel and a plurality of second electrodes arranged in parallel, and the first electrodes and the second electrodes cross with each other to form a touch unit for detecting the presence or absence of a touch operation.

In some embodiments of the disclosure, as shown in FIG. 21, a lens structure (including the lens unit 200i) may be arranged between the touch structure layer 400 and the display substrate 100. In this way, a distance between the lens structure and the light-emitting device is relatively smaller, which is conducive to regulating and controlling the light-emitting angle of the light-emitting device by the lens structure. In addition, with this design, at least part of the lens unit can be configured to be embedded in the encapsulation layer.

In other embodiments of the disclosure, as shown in FIG. 22, the touch structure layer 400 may be arranged between the lens structure (including the lens unit 200i) and the display substrate 100. In this way, a distance between the lens structure and the light-emitting device is relatively smaller, which is conducive to regulating and controlling the light-emitting angle of the light-emitting device by the lens structure.

In the embodiments of the disclosure, the touch electrode 410 may be configured as a continuous electrode structure, that is, the first electrodes and second electrodes are continuous uninterrupted electrode bars, such that the first electrodes and the second electrodes have a larger area to improve the reliability of touch detection; alternatively, the first electrodes and the second electrodes of the touch electrode 410 are grid-like electrodes, meshes of the grid-like electrodes may be configured to correspond to the light-emitting devices, that is, an orthographic projection of a grid line of each of the grid-like electrodes on the display substrate is located in a gap between the sub-pixels to increase the light output rate of the display panel.

In the actual process, the shape of the touch electrode may be selected according to a position relationship of the lens structure and the touch structure layer.

For example, in some embodiments of the disclosure, if the lens structure as shown in FIG. 21 is located between the touch structure layer 400 and the display substrate 100, the touch electrode 410 therein may also be modified to be a continuous electrode structure, that is, the first electrodes and the second electrodes cover the sub-pixels (the light-emitting devices therein), and the first electrodes and the second electrodes are configured as transparent electrodes in this case.

For example, in other embodiments of the disclosure, if the touch structure layer 400 as shown in FIG. 22 is located between the lens structure and the display substrate, the touch electrode 410 may be selected as the grid-like electrode, such that the grid line of the grid-like electrode is blocked by the black matrix 300. In this case, the grid lines may be optionally made of a metal or other materials (which are typically non-transparent materials) having a higher electric conductivity to reduce the electric resistivity of the touch electrode and reduce power consumption.

For example, the display panel provided by the embodiments of the disclosure may be any product or component having a display function, for example, a tablet computer, a television, a display, a laptop computer, a digital photo frame, a navigator, etc.

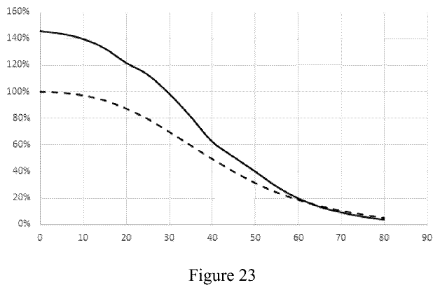

In addition, in order to clearly demonstrate the significant effect of the display panel of the disclosure in improving the light output efficiency, according to an embodiment of the disclosure, analogue simulation of a light effect was performed on the display panel using the previous and later designs of the lens unit provided in the disclosure, and simulation results are shown in FIG. 23. In this description, used design parameters of the display panel provided in the disclosure (the display panel shown in FIG. 9B is taken as an example) include: the refractive index of the first film layer is 1.48-1.5, the refractive index of the first sub-film layer in the second film layer is 1.6, the refractive index of the second sub-film layer in the second film layer is 1.7, a design area of the light-emitting device (a pixel size) is 19 square microns (it is assumed to be in a square shape), and a spacing between the lens unit and the light-emitting device (e.g., the thickness of the encapsulation layer) is 14 microns. A comparative design of the display panel does not include the first sub-film layer described above and includes an additional color film which is located on a side of the lens unit facing away from the display substrate, and the above-mentioned data may be referred for the design parameters of other structures.

The optical simulation results of the display panel provided in the disclosure are denoted by a solid line in FIG. 23, and comparative optical simulation results of the display panel are denoted by a dotted line in FIG. 23, where the abscissa in FIG. 23 represents a viewing angle, and the ordinate represents a normalized light intensity. It can be seen that the light output effect of using the display panel provided in the disclosure is improved by about 43% at the front viewing angle (corresponding to a position where the abscissa is 0).

At least one embodiment of the disclosure further provides a display device, which may include the display panel described above. For example, the display device may further include other functional structures. For example, the display device may further include a touch structure to provide a touch function. For example, the touch structure may be a touch panel or a touch layer, and the touch panel may be arranged on the display panel in an attached manner, for example, the light-emitting side of the display panel; and the touch layer may be prepared directly on the encapsulation layer of the display panel to facilitate the lightweight and thin design of the display panel.

For example, the display device in the embodiments of the disclosure may be any other product or component having a display function, for example, a television, a digital camera, a cell phone, a watch, a tablet computer, a laptop computer, and a navigator.

The above descriptions are merely preferred embodiments of the specification but not intended to limit the specification, and any modifications, equivalent replacements, etc. made within the spirit and principle of the specification should be included within the scope of protection of the specification.

What is claimed is:

1. A display panel, comprising:
a display substrate comprising a plurality of light-emitting devices and a receiving layer located on light-emitting sides of the light-emitting devices; and
a lens structure located on the receiving layer and comprising a plurality of lens units, the lens units being arranged in correspondence with the light-emitting devices;
wherein each of the lens units comprises a color blocking layer configured to absorb light in ambient light that is different in color from light emitted from a corresponding light-emitting device; and
the lens unit has a refractive index greater than a refractive index of the receiving layer.

2. The display panel according to claim 1, wherein the lens unit comprises:
a first film layer comprising a plurality of first recesses corresponding to the light-emitting devices; and
a second film layer, at least part of the second film layer being filled in the first recesses and at least part of the second film layer being configured as the color blocking layer;
wherein the first film layer has a refractive index less than a refractive index of the at least part of the second film layer filled in the first recesses; and
an orthographic projection of each of the light-emitting devices on the display substrate is located within an orthographic projection of the first recess on the display substrate.

3. The display panel according to claim 2, wherein
an orthographic projection of an end, facing the display substrate, of the first recess on the display substrate is located within an orthographic projection of an end, facing away from the display substrate, of the first recess on the display substrate; and
a side wall of the first recess is a planar surface, or the side wall of the first recess is a curved surface protruding toward an inner side of the first recess.

4. The display panel according to claim 2, wherein
the second film layer is the color blocking layer, and the refractive index of the entire second film layer is greater than the refractive index of the first film layer, and
the first recess runs through the first film layer; or
the first recess does not run through the first film layer and is filled with at least part of the second film layer.

5. The display panel according to claim 4, further comprising a black matrix, wherein the black matrix comprises a plurality of openings, the openings correspond to the light-emitting devices, and an orthographic projection of each of the light-emitting devices on the display substrate is located within a corresponding opening.

6. The display panel according to claim 5, wherein
the black matrix is located between the first film layer and the second film layer, and the orthographic projection of the end, facing away from the display substrate, of the first recess on the display substrate coincides with the opening; or
the black matrix is located on a side of the first film layer facing the display substrate, the orthographic projection of the end, facing the display substrate, of the first recess on the display substrate is located within the opening, and the opening is located within the orthographic projection of the end, facing away from the display substrate, of the first recess on the display substrate; or
the black matrix is located on a side of the second film layer facing away from the display substrate, wherein the orthographic projection of the end, facing away from the display substrate, of the first recess on the display substrate coincides with the opening, or the orthographic projection of the end, facing away from the display substrate, of the first recess on the display substrate is located within the opening.

7. The display panel according to claim 2, wherein the second film layer comprises:
a first sub-film layer which is the color blocking layer; and
a second sub-film layer located on a side of the first sub-film layer facing away from the display substrate, wherein a refractive index of the second sub-film layer is greater than the refractive index of the first film layer;
and the refractive index of the second sub-film layer is greater than a refractive index of the first sub-film layer.

8. The display panel according to claim 7, wherein
the first sub-film layer is located between the display substrate and the first film layer, and the first recess runs through the first film layer; and
the orthographic projection of the first recess on the display substrate is located within an orthographic projection of the first sub-film layer on the display substrate, such that the first film layer covers an edge part of the first sub-film layer, and the refractive index of the first sub-film layer is less than the refractive index of the first film layer.

9. The display panel according to claim 8, further comprising a black matrix, wherein the black matrix comprises a plurality of openings, the openings correspond to the light-emitting devices, and an orthographic projection of each of the light-emitting devices on the display substrate is located within a corresponding opening.

10. The display panel according to claim 9, wherein
the black matrix is located on a side of the first film layer facing the display substrate to be in the same layer as the first sub-film layer; or
the black matrix is located between the first film layer and the second sub-film layer, the orthographic projection of the first recess on the display substrate is located within the opening, and the orthographic projection of the first sub-film layer on the display substrate coincides with the opening; or
the black matrix is located on a side of the second film layer facing away from the display substrate, the orthographic projection of the first recess on the display substrate is located within the opening, and the orthographic projection of the first sub-film layer on the display substrate is located within the opening.

11. The display panel according to claim 7, wherein
the first sub-film layer is located on a side of the first film layer facing away from the display substrate and covers the first recess, a part of the first sub-film layer covering the first recess is conformal to the first recess to form a second recess, the second recess is filled with at least part of the second sub-film layer, the refractive index of the first sub-film layer is greater than the refractive index of the first film layer, and
the first recess runs through the first film layer; or the first recess does not run through the first film layer and is filled with at least part of the second film layer.

12. The display panel according to claim 11, wherein the orthographic projection of the end, facing away from the display substrate, of the first recess on the display substrate is located within an orthographic projection of the first sub-film layer on the display substrate; and
a thickness of a part of the first sub-film layer located within the first recess is greater than a thickness of a part of the first sub-film layer located outside the first recess.

13. The display panel according to claim 11, wherein
the first sub-film layer comprises a first main surface facing the display substrate, a second main surface facing away from the display substrate, and a first side surface for connecting the first main surface and the second main surface, wherein the first side surface is a curved surface protruding toward a side of the first sub-film layer facing away from the first recess, and the first side surface is smoothly connected to the second main surface; or
the second sub-film layer comprises a third main surface facing the display substrate, a fourth main surface facing away from the display substrate, and a second side surface for connecting the third main surface and the fourth main surface, wherein the second side surface is a curved surface protruding toward a side of the second sub-film layer facing away from the first recess, the fourth main surface is a curved surface protruding toward the side facing away from the first recess, and the second side surface is smoothly connected to the fourth main surface; or
a refractive index of the part of the first sub-film layer located in the first recess is greater than a refractive index of the part of the first sub-film layer located outside the first recess, and an orthographic projection of the part of the first sub-film layer located outside the first recess on the display substrate is located outside an orthographic projection of the second sub-film layer on the display substrate.

14. The display panel according to claim 11, further comprising a black matrix, wherein the black matrix comprises a plurality of openings corresponding to the lens units, and the orthographic projection of the light-emitting device on the display substrate is located within a corresponding opening.

15. The display panel according to claim 14, wherein
the black matrix is located between the first film layer and the second sub-film layer to be in the same layer as the first sub-film layer, and the orthographic projection of the first sub-film layer on the display substrate is located within the opening; or
the black matrix is located on the side of the first film layer facing the display substrate, the opening is located within the orthographic projection of the first sub-film layer on the display substrate, and the orthographic projection of the end, facing the display substrate, of the first recess on the display substrate is located within the opening; or
the black matrix is located on a side of the second film layer facing away from the display substrate, the orthographic projection of the first recess on the display substrate is located within the opening, and the orthographic projection of the first sub-film layer on the display substrate is located within the opening.

16. The display panel according to claim 1, further comprising:
an array substrate; and
a display function layer located on a side of the array substrate facing the lens structure;
wherein the receiving layer is on a side of the display function layer facing the lens structure and covers the display function layer.

17. The display panel according to claim 16, wherein
the receiving layer is an encapsulation layer.

18. The display panel according to claim 16, wherein
the display substrate comprises an encapsulation layer covering the display function layer, the encapsulation layer comprising a first inorganic layer, a second organic layer and a third inorganic layer that are sequentially superposed on the display function layer, wherein the receiving layer is the third inorganic layer; and
a third recess is provided on a side of the second organic layer facing away from the array substrate, the third inorganic layer is conformal to a surface of the second organic layer facing away from the array substrate to form a fourth recess corresponding to the third recess, the lens structure is at least partially located in the fourth recess, and the first recess is conformal to the fourth recess.

19. The display panel according to claim 1, further comprising:
a touch structure layer located on a light-emitting side of the display substrate and comprising a plurality of first electrodes arranged in parallel and a plurality of second electrodes arranged in parallel, the first electrodes and the second electrodes crossing with each other to form a touch unit;
wherein the first electrodes and the second electrodes are continuous electrode structures, and the lens structure is located between the touch structure layer and the display substrate; or
the first electrodes and the second electrodes are grid-like electrodes, an orthographic projection of a grid line of each of the grid-like electrodes on the display substrate is located in a gap between a plurality of the light-emitting devices, and the touch structure layer is located between the lens structure and the display substrate.

20. A display device, comprising a display panel of claim 1.
